(19) United States
(12) Patent Application Publication
(10) Pub. No.: US 2021/0076140 A1
(43) Pub. Date: Mar. 11, 2021

(54) SURFACE SHAPE VARIABLE SHEET AND SURFACE SHAPE VARIABLE DEVICE

(71) Applicant: JTEKT CORPORATION, Osaka (JP)

(72) Inventor: Takeshi KAWABAYASHI, Kashiba-shi (JP)

(73) Assignee: JTEKT CORPORATION, Osaka (JP)

(21) Appl. No.: 17/012,182

(22) Filed: Sep. 4, 2020

(30) Foreign Application Priority Data
Sep. 9, 2019 (JP) 2019-163970

(51) Int. Cl. H04R 17/00; H01L 41/09

(52) U.S. Cl. CPC H04R 17/005; H02N 2/021; H01L 41/0986

(57) ABSTRACT

A surface shape variable sheet includes: a sheet body made of an elastic material having dielectricity; a first-surface side electrode provided on a first surface side of the sheet body; and a second-surface-side electrode provided on a second surface side that is a back surface of the first surface, the second-surface-side electrode being configured such that a voltage is applied between the second-surface-side electrode and the first-surface-side electrode. The first-surface-side electrode includes: a first electrode facing a first part of the second-surface-side electrode via the sheet body, and a second electrode facing a second part of the second-surface-side electrode via the sheet body, the second electrode being electrically independent from the first electrode on the first surface side.

### CROSS-REFERENCE TO RELATED APPLICATION

This application claims priority to Japanese Patent Application No. 2019-163970 filed on Sep. 9, 2019, incorporated herein by reference in its entirety.

### BACKGROUND

### 1. Technical Field

The present disclosure relates to a surface shape variable sheet and a surface shape variable device.

### 2. Description of Related Art

Japanese Unexamined Patent Application Publication (Translation of PCT Application) No. 2007-534283 (JP 2007-534283 A) describes a device configured to change the surface shape of a sheet made of a polymer. The device includes a sheet made of a polymer having dielectricity, and a pair of electrodes configured such that the electrodes are provided on the opposite surfaces of the sheet so as to face each other via the sheet. When a voltage is applied between the electrodes, coulomb force is generated between the electrodes, so that a distance between the electrodes is changed. This deforms the sheet, so that the surface shape of the sheet is changed.

### SUMMARY

The device described in JP 2007-534283 A is configured to switch between a state where the surface shape of the sheet is deformed and a state where the surface shape of the sheet is not deformed, based on whether or not a voltage is applied between the electrodes. That is, a deformation pattern obtained at the time when the surface shape of the sheet is deformed cannot be switched to another deformation pattern.

The present disclosure can switch a plurality of deformation patterns on a sheet surface from one to another.

A first aspect of the present disclosure relates to a surface shape variable sheet. The surface shape variable sheet includes a sheet body, a first-surface-side electrode, and a second-surface-side electrode. The sheet body is made of an elastic material having dielectricity. The first-surface-side electrode is provided on a first surface side of the sheet body. The second-surface-side electrode is provided on a second surface side that is a back surface of the first surface, the second-surface-side electrode being configured such that a voltage is applied between the second-surface-side electrode and the first-surface-side electrode. The first-surface-side electrode includes a first electrode and a second electrode.

The first electrode faces a first part of the second-surface-side electrode via the sheet body. The second electrode faces a second part of the second-surface-side electrode via the sheet body. The second electrode is electrically independent from the first electrode on the first surface side.

In the above configuration, the first-surface-side electrode includes the first electrode and the second electrode that are electrically independent from each other. Accordingly, as the first-surface-side electrode, either or both of the first electrode and the second electrode can be used selectively. Hereby, it is possible to switch the following cases from one to another: a case where the sheet surface is deformed in a part where the second-surface-side electrode faces the first electrode; a case where the sheet surface is deformed in a part where the second-surface-side electrode faces the second electrode; and a case where the sheet surface is deformed in both of the parts. As a result, a plurality of deformation patterns to be obtained at the time when the sheet surface is deformed can be switched from one to another.

In the surface shape variable sheet, the first electrode may include a first linear pattern. The second electrode may include a second linear pattern extending along the same linear direction as the first linear pattern and arranged with the first linear pattern. The second-surface-side electrode may include a second-surface-side linear pattern including one or more first facing portions facing the first linear pattern and one or more second facing portions facing the second linear pattern. With the above configuration, deformations can be caused in respective parts of the sheet surface, the respective parts corresponding to the first facing portions and the second facing portions.

In the surface shape variable sheet, the one or more first facing portions may be different from the one or more second facing portions in terms of at least one of length and linewidth. With the above configuration, the deformations caused in the respective parts corresponding to both facing portions can have different shapes. As a result, different surface characteristics such as surface roughness on the sheet surface can be achieved for respective deformation patterns, thereby making it possible to switch the surface characteristics of the sheet surface.

In the surface shape variable sheet, an arrangement distance between the first facing portions along the linear direction may be different from an arrangement distance between the second facing portions along the linear direction. With the above configuration, the deformations caused in the respective parts corresponding to both facing portions can have different arrangements.

In the surface shape variable sheet, the one first facing portion and the one second facing portion may each include a first linear portion, and a second linear portion extending in a direction intersecting with a linear direction of the first linear portion. A first end of the second linear portion may be connected to a first end of the first linear portion. The one first facing portion may be different from the one second facing portion in terms of a direction directed from second ends of the first linear portion and the second linear portion toward the first ends of the first linear portion and the second linear portion on a bisector that divides in half an angle formed between the first linear portion and the second linear portion. With the above configuration, the directionality of the deformation shape that appears in the parts corresponding to the first facing portions can be made different from the directionality of the deformation shape that appears in the parts corresponding to the second facing portions. Hereby, the directionalities of the deformation patterns on the sheet surface can be switched.

In the surface shape variable sheet, the one first facing portion and the one second facing portion may be formed in a linear shape and be placed to be distanced from each other. Extension lines along respective linear directions of the one first facing portion and the one second facing portion may intersect with each other. With the above configuration, the directionalities of the deformation patterns on the sheet surface can be switched.

In the surface shape variable sheet, the second-surface-side electrode may include a third electrode facing at least one of the first electrode and the second electrode via the sheet body, and a fourth electrode facing at least one of the first electrode and the second electrode via the sheet body. In the above configuration, the second-surface-side electrode includes the third electrode and the fourth electrode. Accordingly, the number of combinations of electrodes to which a voltage is applied at the time when the voltage is applied between the first-surface-side electrode and the second-surface-side electrode can be increased more. As a result, it is possible to increase the number of deformation patterns on the sheet surface.

The surface shape variable sheet may further include another sheet body made of an elastic material having dielectricity and laminated on either of the first surface and the second surface. In the above configuration, for example, in a case where another sheet is laminated on the second surface, when the second-surface-side electrode is provided to another sheet, and the sheet and another sheet are laminated such that a surface, of the another sheet, on which the second-surface-side electrode is provided is put on the second surface side of the sheet, the surface shape variable sheet can be easily obtained.

A second aspect of the present disclosure relates to a surface shape variable device. The surface shape variable device includes a surface shape variable sheet, a power supply, a first switch, and a second switch. The surface shape variable sheet includes: a sheet body made of an elastic material having dielectricity; a first-surface-side electrode provided on a first surface side of the sheet body; and a second-surface-side electrode provided on a second surface side that is a back surface of the first surface, the second-surface-side electrode being configured such that a voltage is applied between the second-surface-side electrode and the first-surface-side electrode. The first-surface-side electrode includes: a first electrode facing a first part of the second-surface-side electrode via the sheet body; and a second electrode facing a second part of the second-surface-side electrode via the sheet body, the second electrode being electrically independent from the first electrode on the first surface side. The power supply is configured to apply a voltage between the first-surface-side electrode and the second-surface-side electrode. The first switch is provided between the power supply and the first electrode. The second switch is provided between the power supply and the second electrode. With the above configuration, a plurality of deformation patterns on the sheet surface can be switched from one to another.

In accordance with the present disclosure, it is possible to switch a plurality of deformation patterns on a sheet surface from one to another.

### BRIEF DESCRIPTION OF THE DRAWINGS

Features, advantages, and technical and industrial significance of exemplary embodiments of the disclosure will be described below with reference to the accompanying drawings, in which like signs denote like elements, and wherein:

FIG. 1 is a view illustrating a surface shape variable device according to a first embodiment;

FIG. 2A is a partial sectional view of a surface shape variable sheet;

FIG. 2B is a perspective view to describe the configuration of the surface shape variable sheet;

FIG. 3 is a graph illustrating one example of the displacement of a surface shape variable sheet 2 to an applied voltage in a part where electrodes face each other;

FIG. 4A is a view illustrating an exemplary configuration of a first-surface-side electrode provided on a first surface;

FIG. 4B is a view illustrating an exemplary configuration of a second-surface-side electrode provided on a first surface of a second dielectric sheet;

FIG. 5 is a view illustrating a positional relationship between a second-surface-side linear pattern and each electrode of the first-surface-side electrode in a plan view of a deformable surface of the surface shape variable sheet;

FIG. 6A is a view illustrating a deformation pattern to appear on the deformable surface in accordance with switching by a switch;

FIG. 6B is a view illustrating a deformation pattern to appear on the deformable surface in accordance with switching by the switch;

FIG. 6C is a view illustrating a deformation pattern to appear on the deformable surface in accordance with switching by the switch;

FIG. 6D is a view illustrating a deformation pattern to appear on the deformable surface in accordance with switching by the switch;

FIG. 7A is a view illustrating a deformation pattern to appear on the deformable surface in accordance with switching by the switch;

FIG. 7B is a view illustrating a deformation pattern to appear on the deformable surface in accordance with switching by the switch;

FIG. 7C is a view illustrating a deformation pattern to appear on the deformable surface in accordance with switching by the switch;

FIG. 8A is a view illustrating an exemplary configuration of a first-surface-side electrode according to a second embodiment;

FIG. 8B is a view illustrating an exemplary configuration of a second-surface-side electrode according to the second embodiment;

FIG. 9A is a view illustrating a positional relationship between a second-surface-side linear pattern and each electrode of the first-surface-side electrode in a plan view of a deformable surface of a surface shape variable sheet according to the second embodiment;

FIG. 9B is a view illustrating a first facing portion and a second facing portion in a plan view of the deformable surface of the surface shape variable sheet according to the second embodiment;

FIG. 10A is a view illustrating a deformation pattern to appear on the deformable surface in the second embodiment;

FIG. 10B is a view illustrating a deformation pattern to appear on the deformable surface in the second embodiment;

FIG. 10C is a view illustrating a deformation pattern to appear on the deformable surface in the second embodiment;

FIG. 11A is a view illustrating a positional relationship between a second-surface-side linear pattern and each electrode of a first-surface-side electrode in a plan view of a deformable surface of a surface shape variable sheet according to a modification of the second embodiment;

FIG. 11B is a view illustrating a first facing portion and a second facing portion in a plan view of the deformable surface of the surface shape variable sheet according to the modification of the second embodiment;

FIG. 12A is a view illustrating a deformation pattern to appear on the deformable surface in the modification;

FIG. 12B is a view illustrating a deformation pattern to appear on the deformable surface in the modification; and

FIG. 12C is a view illustrating a deformation pattern to appear on the deformable surface in the modification.

### DETAILED DESCRIPTION OF EMBODIMENTS

Preferred embodiments of the present disclosure will be described below with reference to the attached drawings.

### First Embodiment

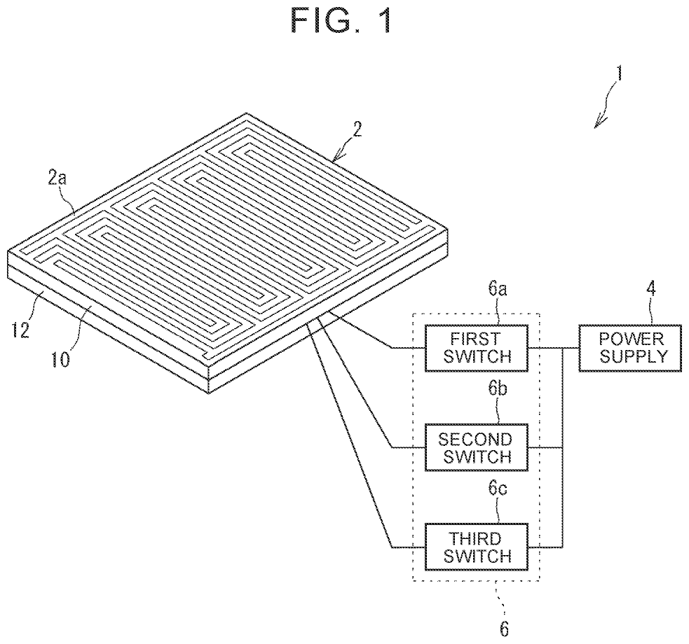

FIG. 1 is a view illustrating a surface shape variable device according to a first embodiment. In FIG. 1, the surface shape variable device 1 includes a surface shape variable sheet 2, a power supply 4, and a switch 6. The surface shape variable device 1 is a device configured to change a surface shape of a deformable surface 2a that is a surface of the surface shape variable sheet 2. The surface shape variable sheet 2 is, for example, provided in a conveying device (e.g., a conveyance robot, a conveyance conveyer, and the like) configured to convey a conveyed object such that the surface shape variable sheet 2 is placed in a part where the surface shape variable sheet 2 abuts with the conveyed object. The surface shape variable sheet 2 is used to control frictional force between the conveyed object and the conveying device.

The surface shape variable sheet 2 has a first layer 10 on the deformable surface 2a side, and a second layer 12 laminated on the first layer 10. The surface shape variable sheet 2 is configured such that, when a voltage is applied to an electrode provided in the surface shape variable sheet 2, the surface shape variable sheet 2 is brought into a deformed state where the deformable surface 2a deforms, and when the application of the voltage is stopped, the surface shape variable sheet 2 is brought into a non-deformation state that is an original state where no deformation occurs.

The power supply 4 is connected to the surface shape variable sheet 2 via the switch 6. The power supply 4 is connected to a first-surface-side electrode 22 and a second-surface-side electrode 24 provided in the surface shape variable sheet 2 and applies a voltage between the electrodes 22, 24. The switch 6 is connected between the first-surface-side electrode 22 and the power supply 4. The switch 6 includes a first switch 6a, a second switch 6b, and a third switch 6c. As will be described later, the first-surface-side electrode 22 includes a first electrode 30, a second electrode 32, and a third electrode 34. The first switch 6a is connected between the power supply 4 and the first electrode 30. The second switch 6b is connected between the power supply 4 and the second electrode 32. The third switch 6c is connected between the power supply 4 and the third electrode 34. The switch 6 switches connection modes between the surface shape variable sheet 2 and the power supply 4 by connecting and disconnecting the switches 6a, 6b, 6c so that the deformable surface 2a can be deformed, and a plurality of deformation patterns to be obtained at the time when the deformable surface 2a is deformed can be switched from one to another.

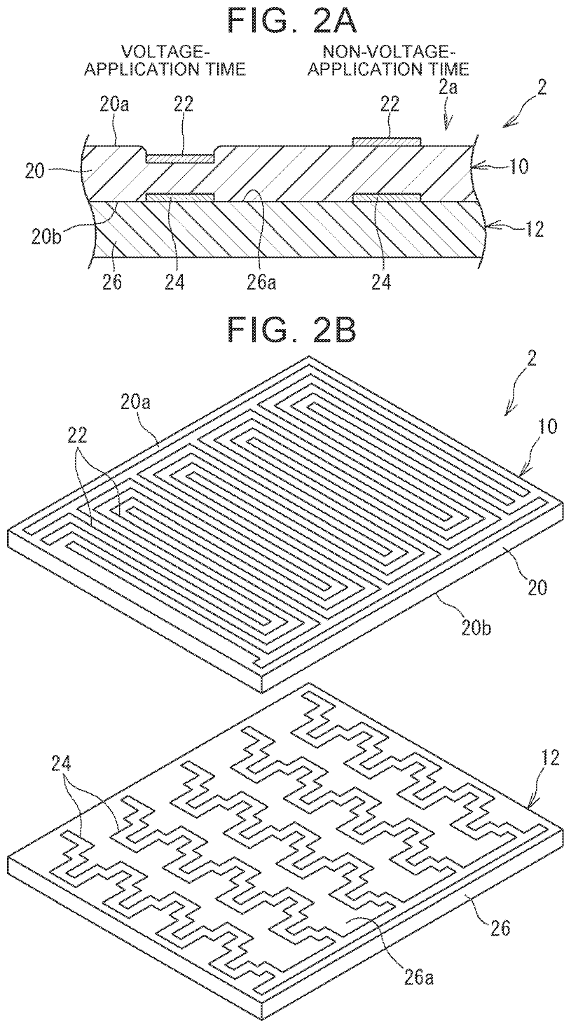

FIG. 2A is a partial sectional view of the surface shape variable sheet 2, and FIG. 2B is a perspective view to describe the configuration of the surface shape variable sheet 2. Note that, in FIG. 2B, the first layer 10 and the second layer 12 are illustrated separately.

The surface shape variable sheet 2 includes: a first dielectric sheet 20 a first surface 20a side of which serves as the deformable surface 2a; the first-surface-side electrode 22 provided on the first surface 20a side of the first dielectric sheet 20; the second-surface-side electrode 24 provided on a second surface 20b side of the first dielectric sheet 20; and a second dielectric sheet 26 laminated on the second surface 20b side.

The first dielectric sheet 20 and the second dielectric sheet 26 are made of an elastic material having dielectricity. As an elastic body having dielectricity, dielectric elastomer such as silicon rubber or nitrile rubber is used. In the present embodiment, the thickness of the dielectric sheets 20, 26 is set to 50 μm. Note that the thickness of the dielectric sheets 20, 26 can be changed appropriately within a range from dozens of micrometers to hundreds of micrometers as needed.

The first-surface-side electrode 22 is made of a conductive material such as copper, gold, or graphite. The first-surface-side electrode 22 is formed by performing pattern printing of the conductive material on the first surface 20a. The first-surface-side electrode 22 includes a plurality of linear patterns as linear electrodes as illustrated in FIG. 2B.

Similarly to the first-surface-side electrode 22, the second-surface-side electrode 24 is made of a conductive material such as copper, gold, or graphite. The second-surface-side electrode 24 is provided between the first dielectric sheet 20 and the second dielectric sheet 26. The second-surface-side electrode 24 is formed by performing pattern printing of the conductive material on a first surface 26a of the second dielectric sheet 26. The second-surface-side electrode 24 includes a plurality of linear patterns as linear electrodes as illustrated in FIG. 2B.

As illustrated in FIG. 2A, the first-surface-side electrode 22 and the second-surface-side electrode 24 have parts facing each other via the first dielectric sheet 20. A direct voltage is applied by the power supply 4 between the first-surface-side electrode 22 and the second-surface-side electrode 24. When the direct voltage is applied between the electrodes 22, 24, coulomb force is generated between the electrodes 22, 24, so that a distance between the electrodes 22, 24 changes to become narrow in comparison with a non-voltage-application time. Hereby, a part of the deformable surface 2a of the first dielectric sheet 20, the part corresponding to a part where the electrodes 22, 24 face each other, deforms to be recessed, so that the surface shape of the deformable surface 2a is changed.

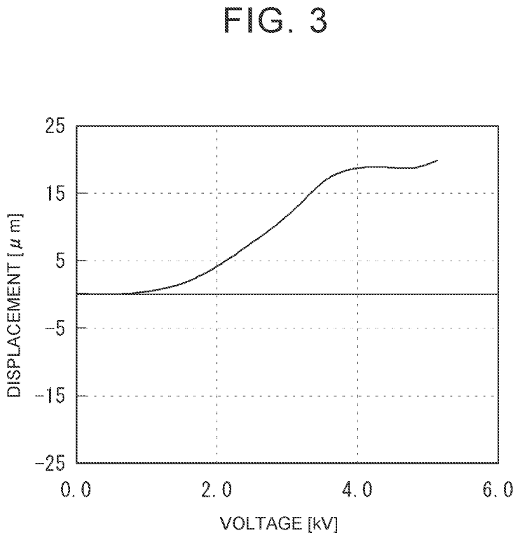

FIG. 3 is a graph illustrating one example of the displacement of the surface shape variable sheet 2 to an applied voltage in the part where electrodes 22, 24 face each other. In the figure, the horizontal axis indicates an applied voltage (kV) and the vertical axis indicates a displacement (μm) by which the deformable surface 2a (the first surface 20a) is recessed due to deformation. As illustrated in FIG. 3, it is found that, as the applied voltage increases, the displacement of the deformable surface 2a increases, and the deformable surface 2a is displaced by about 20 μm at the maximum.

As described above, when a voltage is applied to the surface shape variable sheet 2, a deformation occurs in the part where the first-surface-side electrode 22 and the second-surface-side electrode 24 face each other, so that the surface shape as the whole deformable surface 2a changes.

Referring back to FIGS. 2A, 2B, the surface shape variable sheet 2 is configured such that the first layer 10 and the second layer 12 are provided in a laminated manner as described above. The first layer 10 is the first dielectric sheet 20 provided with the first-surface-side electrode 22. The second layer 12 is the second dielectric sheet 26 provided with the second-surface-side electrode 24. By providing the first layer 10 and the second layer 12 in a laminated manner, the second-surface-side electrode 24 can be provided on the second surface 20b side of the first dielectric sheet 20.

For example, in a case where pattern printing is to be performed on both the first surface 20a and the second surface 20b of the first dielectric sheet 20, it may be difficult to perform pattern printing depending on the thickness of the first dielectric sheet 20. In this respect, in the present embodiment, the second dielectric sheet 26 is included as another sheet body. On this account, when the second-surface-side electrode 24 is formed on the first surface 26a of the second dielectric sheet 26, and the first layer 10 and the second layer 12 are laminated, the second-surface-side electrode 24 can be provided on the second surface 20b side of the first dielectric sheet 20 without performing printing on the second surface 20b of the first dielectric sheet 20. Thus, the surface shape variable sheet 2 can be easily obtained.

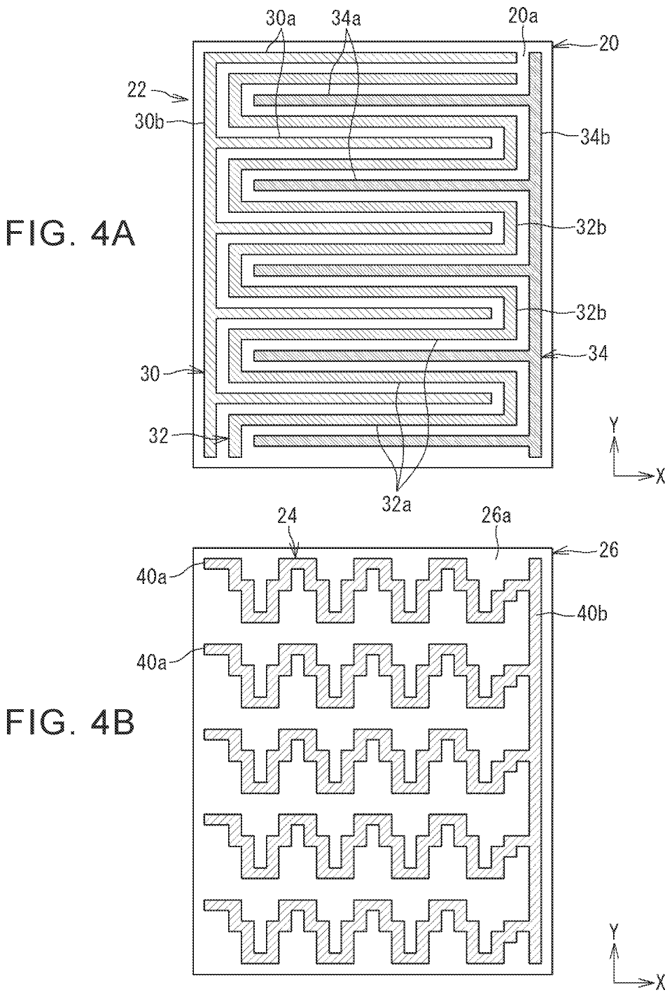

FIG. 4A is a view illustrating an exemplary configuration of the first-surface-side electrode 22 provided on the first surface 20a. Note that two directions perpendicular to each other in FIG. 4A are referred to as an X-direction and a Y-direction. This also applies to the following figures. As illustrated in FIG. 4A, the first-surface-side electrode 22 includes the first electrode 30, the second electrode 32, and the third electrode 34.

The first electrode 30 includes a plurality of first linear patterns 30a extending linearly along the X-direction, and a connection pattern 30b extending along the Y-direction so as to connect the first linear patterns 30a to each other. The second electrode 32 includes a plurality of second linear patterns 32a extending linearly along the X-direction, and a connection pattern 32b extending along the Y-direction so as to connect the second linear patterns 32a to each other. The third electrode 34 includes a plurality of third linear patterns 34a extending linearly along the X-direction, and a connection pattern 34b extending along the Y-direction so as to connect the third linear patterns 34a to each other.

The first electrode 30 is formed in a comb shape in which the first linear patterns 30a extend from the connection pattern 30b. The third electrode 34 is formed in a comb shape in which the third linear patterns 34a extend from the connection pattern 34b. In the meantime, the second electrode 32 is formed to constitute one pattern by connecting a first end of one second linear pattern 32a to a second end of its adjacent second linear pattern 32a by the connection pattern 32b. Respective linewidths of the patterns 30a, 30b, 32a, 32b, 34a,34b constituting the electrodes 30, 32, 34 are set to the same dimension.

The first linear patterns 30a, the second linear patterns 32a, and the third linear patterns 34a extending along the X-direction are placed in parallel to each other at predetermined intervals, and they are arranged along the same linear direction. Further, the first linear patterns 30a, the second linear patterns 32a, and the third linear patterns 34a are placed to be arranged in the Y-direction in a predetermined order.

As illustrated in FIG. 4A, the electrodes 30, 32, 34 are provided on the first surface 20a so as to be electrically independent from each other without being connected to each other. Note that to be electrically independent as used herein indicates a state where a plurality of electrodes formed on the same surface is not connected to each other, and when a voltage is applied to a given electrode among the electrodes, the voltage is not applied to the electrodes other than the given electrode.

FIG. 4B is a view illustrating an exemplary configuration of the second-surface-side electrode 24 provided on the first surface 26a of the second dielectric sheet 26. As illustrated in FIG. 4B, the second-surface-side electrode 24 includes: a plurality of second-surface-side linear patterns 40a extending in a zig-zag manner along the X-direction; and a connection pattern 40b extending along the Y-direction so as to connect the second-surface-side linear patterns 40a to each other. The second-surface-side linear patterns 40a are placed to be arranged in the Y-direction at predetermined intervals. Unlike the first-surface-side electrode 22, the second-surface-side electrode 24 does not include a plurality of electrodes electrically independent from each other, and the second-surface-side electrode 24 constitutes a single electrode.

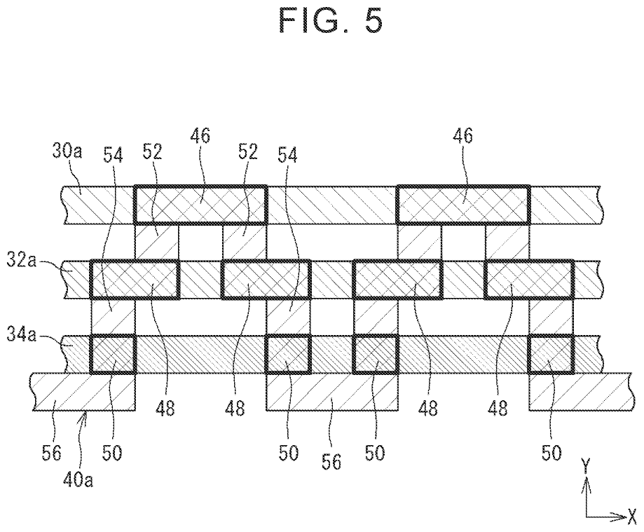

FIG. 5 is a view illustrating a positional relationship between the second-surface side linear pattern 40a and each of the electrodes 30, 32, 34 of the first-surface-side electrode 22 in a plan view of the deformable surface 2a of the surface shape variable sheet 2. As illustrated in FIG. 5, one second-surface-side linear pattern 40a extends in a zig-zag manner along the X-direction so as to overlap each of the linear patterns 30a, 32a, 34a of the electrodes 30, 32, 34 at a plurality of parts. Accordingly, the one second-surface-side linear pattern 40a faces the each of the linear patterns 30a, 32a, 34a of the electrodes 30, 32, 34 at the parts.

The second-surface-side linear pattern 40a includes: a plurality of first facing portions 46 facing the first linear pattern 30a; a plurality of second facing portions 48 facing the second linear pattern 32a; and a plurality of third facing portions 50 facing the third linear pattern 34a.

The first facing portions 46 are provided along the first linear pattern 30a and are formed in a linear shape having the same linewidth as the first linear pattern 30a. The second facing portions 48 are provided along the second linear pattern 32a and are formed in a linear shape having the same linewidth as the second linear pattern 32a. The third facing portions 50 are regions where the second-surface-side linear pattern 40a intersects with the third linear pattern 34a. The length along the extending direction of the second-surface-side linear pattern 40a is longest in the first facing portions 46 and becomes shorter sequentially in order of the second facing portions 48 and the third facing portions 50. Further, the facing portions 46, 48, 50 are placed to have different pitches (arrangement distances) in the X-direction.

Respective first ends of the second facing portions 48 are connected to the opposite ends of the first facing portion 46 via respective connecting portions 52 provided along the Y-direction. A first end of the third facing portion 50 is connected to a second end of the second facing portion 48 via a connecting portion 54 provided along the Y-direction. To a second end of the third facing portion 50, a second end of its adjacent third facing portion 50 is connected via a connecting portion 56 provided along the X-direction.

When a voltage is applied between the second-surface-side electrode 24 and the first electrode 30, a distance between the first electrode 30 and each of the first facing portions 46 in the second-surface-side electrode 24 changes to become narrow. Hereby, parts of the deformable surface 2a of the surface shape variable sheet 2, the parts corresponding to the first facing portions 46, deform to be recessed. When a voltage is applied between the second-surface-side electrode 24 and the second electrode 32, a distance between the second electrode 32 and each of the second facing portions 48 in the second-surface-side electrode 24 changes to become narrow. Hereby, parts of the deformable surface 2a, the parts corresponding to the second facing portions 48, deform to be recessed. When a voltage is applied between the second-surface-side electrode 24 and the third electrode 34, a distance between the third electrode 34 and each of the third facing portions 50 in the second-surface-side electrode 24 changes to become narrow. Hereby, parts of the deformable surface 2a, the parts corresponding to the third facing portions 50, deform to be recessed. Thus, deformation can be caused in the parts of the deformable surface 2a, the parts corresponding to the facing portions 46, 48, 50.

The contour of a deformed part caused in a part corresponding to each of the facing portions 46, 48, 50 is determined by the contour shape of the each of the facing portions 46, 48, 50. Since the facing portions 46, 48, 50 have different lengths, the deformed parts caused in respective parts corresponding to the facing portions 46, 48, 50 have different contours in accordance with the facing portions 46, 48, 50.

The electrodes 30, 32, 34 are connected to the power supply 4 via the switch 6 (FIG. 1). The switch 6 has a function to connect and disconnect the power supply 4 to and from each of the electrodes 30, 32, 34. For example, in a case where the first electrode 30 and the second electrode 32 are selected such that a voltage is applied between the second-surface-side electrode 24 and each of the first electrode 30 and the second electrode 32, the power supply 4 is connected to the first electrode 30 via the first switch 6a of the switch 6, and the power supply 4 is connected to the second electrode 32 via the second switch 6b. In this case, the voltage is applied between the second-surface-side electrode 24 and each of the first electrode 30 and the second electrode 32. As such, the switch 6 can switch the electrodes 30, 32, 34 such that a voltage is applied between a selected electrode and the second-surface-side electrode 24.

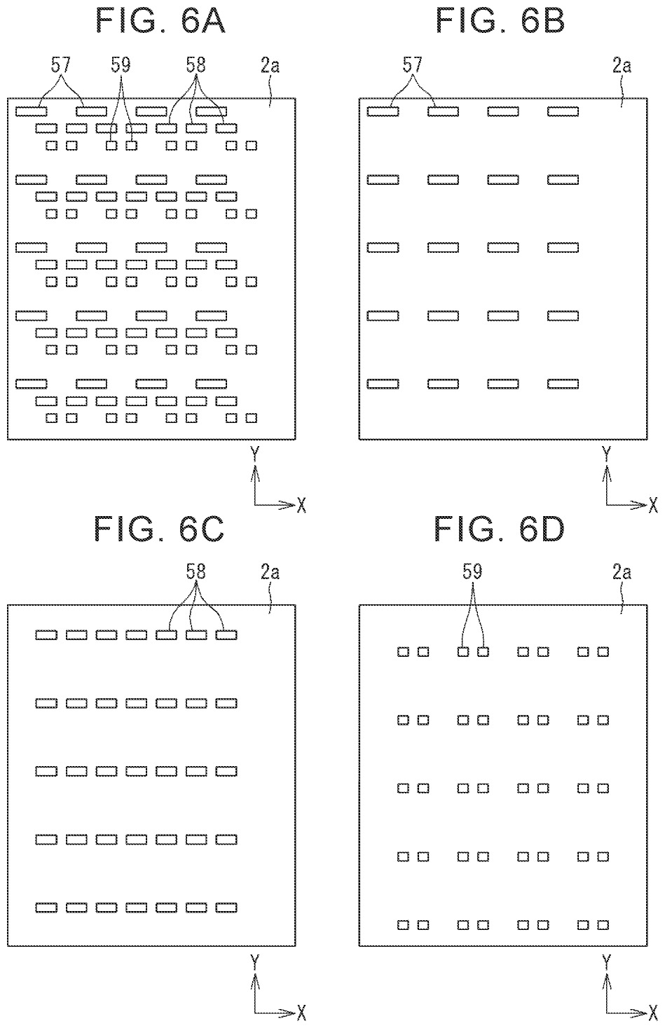

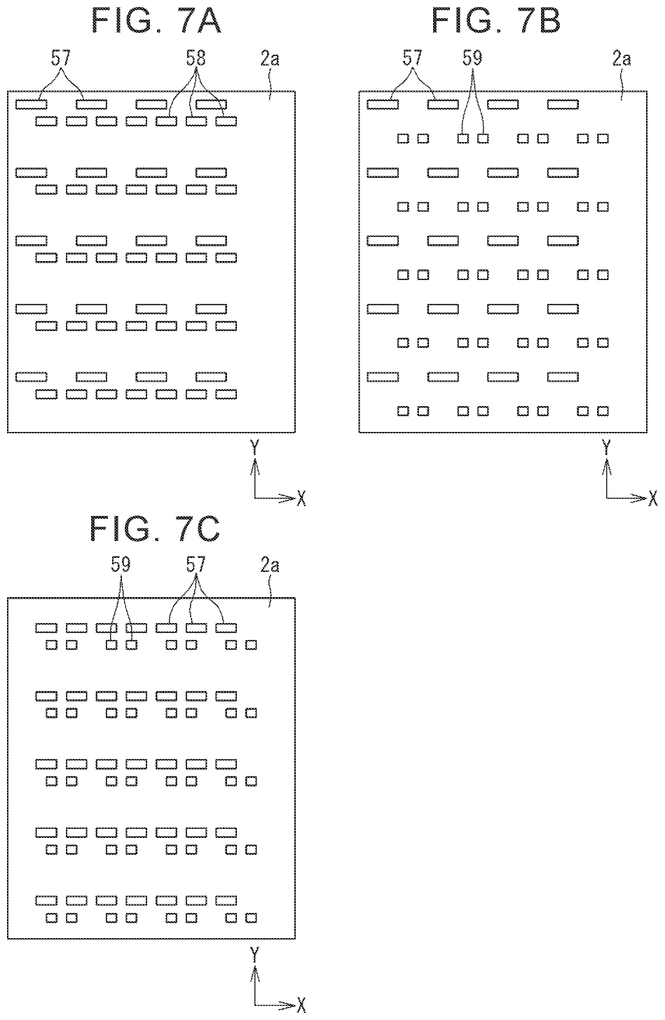

FIGS. 6A to 7C are views each illustrating a deformation pattern to appear on the deformable surface 2a in accordance with switching by the switch 6. The deformation patterns illustrated in FIGS. 6A to 7C are constituted by a plurality of recesses appearing in corresponding parts of the deformable surface 2a when a voltage is applied between the second-surface-side electrode 24 and the first-surface-side electrode 22.

FIG. 6A illustrates a deformation pattern when a voltage is applied between the second-surface-side electrode 24 and all the electrodes 30, 32, 34 included in the first-surface-side electrode 22. In FIG. 6A, a plurality of first recesses 57 is recesses to appear in parts corresponding to the first facing portions 46. A plurality of second recesses 58 is recesses to appear in parts corresponding to the second facing portions 48. A plurality of third recesses 59 is recesses to appear in parts corresponding to the third facing portions 50.

As described above, the length along the extending direction of the second-surface-side linear pattern 40a is longest in the first facing portions 46 and becomes shorter sequentially in order of the second facing portions 48 and the third facing portions 50. Accordingly, the first recess 57 corresponding to the first facing portion 46 has the longest length among the recesses 57, 58, 59. Further, the facing portions 46, 48, 50 are placed at different pitches in the X-direction. Accordingly, the recesses 57, 58, 59 appear at different pitches in the X-direction.

FIG. 6B illustrates a deformation pattern when a voltage is applied between the second-surface-side electrode 24 and the first electrode 30 of the first-surface-side electrode 22, and no voltage is applied to the second electrode 32 and the third electrode 34. In this case, only the first recesses 57 appear on the deformable surface 2a so as to correspond to the first facing portions 46.

FIG. 6C illustrates a deformation pattern when a voltage is applied between the second-surface-side electrode 24 and the second electrode 32 of the first-surface-side electrode 22, and no voltage is applied to the first electrode 30 and the third electrode 34. In this case, only the second recesses 58 appear on the deformable surface 2a so as to correspond to the second facing portions 48.

FIG. 6D illustrates a deformation pattern when a voltage is applied between the second-surface-side electrode 24 and the third electrode 34 of the first-surface-side electrode 22, and no voltage is applied to the first electrode 30 and the second electrode 32. In this case, only the third recesses 59 appear on the deformable surface 2a so as to correspond to the third facing portions 50.

FIG. 7A illustrates a deformation pattern when a voltage is applied between the second-surface-side electrode 24 and each of the first electrode 30 and the second electrode 32 of the first-surface-side electrode 22, and no voltage is applied to the third electrode 34. In this case, the first recesses 57 and the second recesses 58 appear on the deformable surface 2a so as to correspond to the first facing portions 46 and the second facing portions 48.

FIG. 7B illustrates a deformation pattern when a voltage is applied between the second-surface-side electrode 24 and each of the first electrode 30 and the third electrode 34 of the first-surface-side electrode 22, and no voltage is applied to the second electrode 32. In this case, the first recesses 57 and the third recesses 59 appear on the deformable surface 2a so as to correspond to the first facing portions 46 and the third facing portions 50.

FIG. 7C illustrates a deformation pattern when a voltage is applied between the second-surface-side electrode 24 and each of the second electrode 32 and the third electrode 34 of the first-surface-side electrode 22, and no voltage is applied to the first electrode 30. In this case, the second recesses 58 and the third recesses 59 appear on the deformable surface 2a so as to correspond to the second facing portions 48 and the third facing portions 50.

As described above, in the present embodiment, the first-surface-side electrode 22 includes the first electrode 30, the second electrode 32, and the third electrode 34 that are electrically independent from each other. Accordingly, as the first-surface-side electrode 22, part of or all of the electrodes 30, 32, 34 can be used selectively. As a result, the deformation patterns to be obtained at the time when the deformable surface 2a is deformed can be switched from one to another.

Further, in the present embodiment, the facing portions 46, 48, 50 have different lengths and different pitches (arrangement distances) in the X-direction. Accordingly, deformations caused in respective parts corresponding to the facing portions 46, 48, 50 can have different shapes and different arrangements from each other. As a result, different surface characteristics such as surface roughness in the deformable surface 2a can be achieved for respective deformation patterns, thereby making it possible to switch the surface characteristics of the deformable surface 2a.

By switching the surface characteristics such as surface roughness in the deformable surface 2a, it is possible to control frictional force between the conveyed object and the conveying device. Thus, it is possible to control the surface characteristics of the deformable surface 2a so that appropriate frictional force can be achieved in accordance with weight, surface characteristics, and so on of the conveyed object.

### Second Embodiment

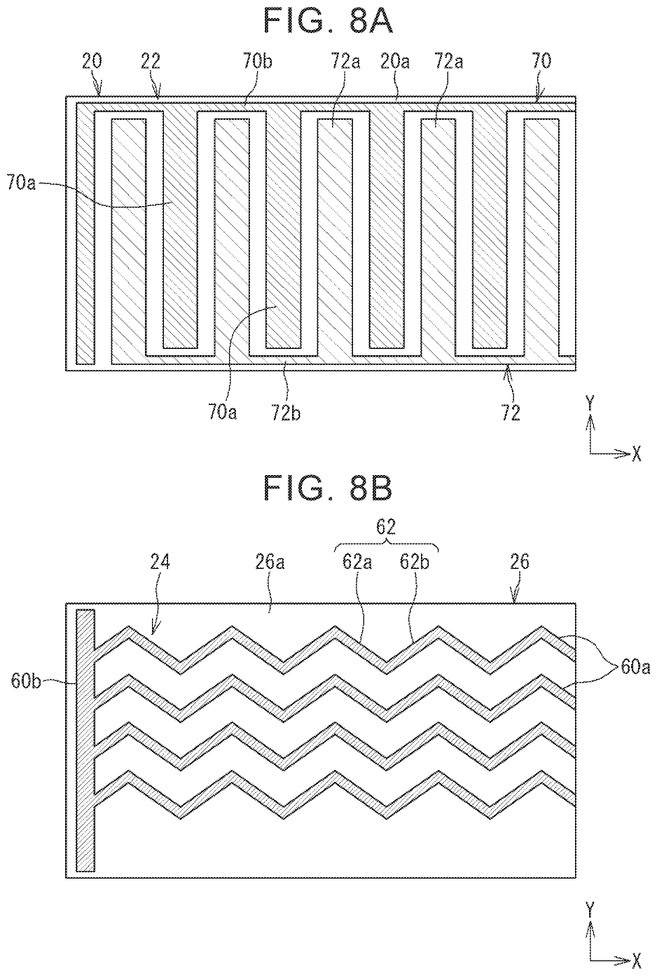

FIG. 8A is a view illustrating an exemplary configuration of the first-surface-side electrode 22 according to a second embodiment, and FIG. 8B is a view illustrating an exemplary configuration of the second-surface-side electrode 24 according to the second embodiment. The present embodiment is different from the first embodiment in that the first-surface-side electrode 22 includes two electrodes, i.e., a first electrode 70 and a second electrode 72, and the second-surface-side electrode 24 constitutes a single electrode having a herringbone-shaped linear pattern.

As illustrated in FIG. 8A, the first-surface-side electrode 22 provided on the first surface 20a includes the first electrode 70 and the second electrode 72. The first electrode 70 includes a plurality of first linear patterns 70a extending linearly along the Y-direction, and a connection pattern 70b extending along the X-direction so as to connect the first linear patterns 70a to each other. The second electrode 72 includes a plurality of second linear patterns 72a extending linearly along the Y-direction, and a connection pattern 72b extending along the X-direction so as to connect the second linear patterns 72a to each other.

The first electrode 70 and the second electrode 72 are formed in a comb shape in which the first linear patterns 70a and the second linear patterns 72a extend from the connection patterns 70b, 72b, respectively. The linewidth of the first linear pattern 70a and the linewidth of the second linear pattern 72a are uniform along their linear directions and are set to the same dimension. The first linear patterns 70a and the second linear patterns 72a are placed in parallel to each other at predetermined intervals. Further, the first linear patterns 70a and the second linear patterns 72a are placed to be alternately arranged in the X-direction.

As illustrated in FIG. 8A, the first electrode 70 and the second electrode are provided on the first surface 20a so as to be electrically independent from each other without being connected to each other.

As illustrated in FIG. 8B, the second-surface-side electrode 24 provided on the first surface 26a of the second dielectric sheet 26 includes a plurality of herringbone-shaped second-surface-side linear patterns 60a extending along the X-direction, and a connection pattern 60b extending along the Y-direction so as to connect the second-surface-side linear patterns 60a to each other. The second-surface-side linear patterns 60a are placed to be arranged in the Y-direction at predetermined intervals.

The linewidth of the second-surface-side linear pattern 60a is uniform along its linear direction. The second-surface-side linear pattern 60a is formed in a herringbone shape such that V-shaped portions 62 having a V-shape opened toward a first side in the Y-direction (the upper side on the plane of paper) are connected to each other in the X-direction. The V-shaped portion 62 is constituted by a first inclined portion 62a and a second inclined portion 62b. The V-shaped portion 62 is linearly symmetric across a straight line parallel to the Y-direction, the straight line passing through a distal end portion where the inclined portions 62a, 62b are connected to each other. Accordingly, the inclined portions 62a, 62b are inclined in different inclination directions inclined from the Y-direction.

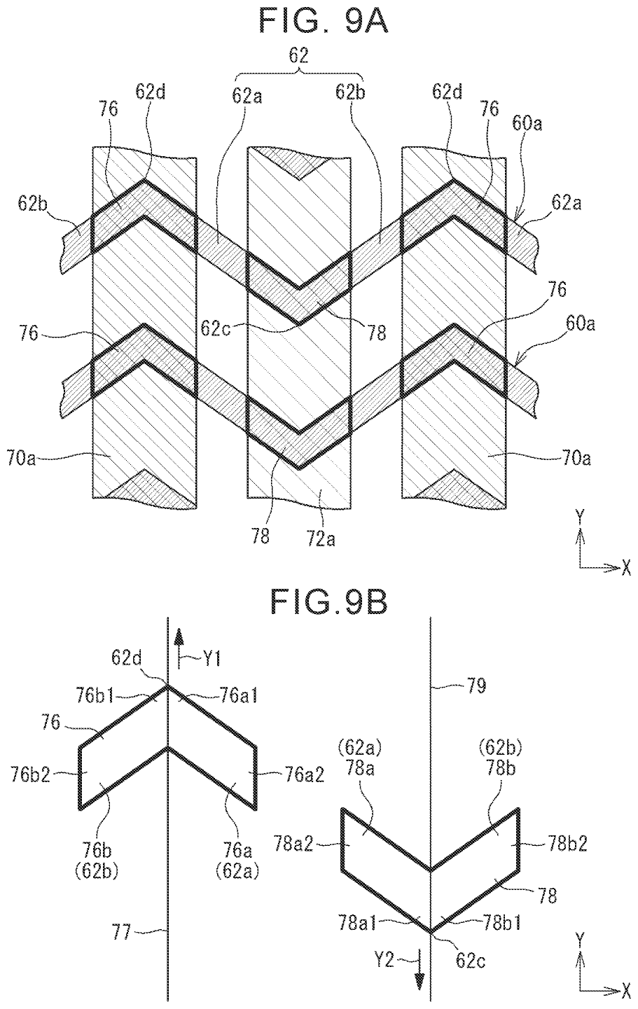

FIG. 9A is a view illustrating a positional relationship between the second-surface side linear pattern 60a and each of the electrodes 70, 72 of the first-surface-side electrode 22 in a plan view of the deformable surface 2a of the surface shape variable sheet 2 according to the second embodiment. As illustrated in FIG. 9A, respective linewidths of the first linear patterns 70a and the second linear patterns 72a are set to be larger than the linewidth of the second-surface-side linear patterns 60a. One second-surface-side linear pattern 60a intersects with one first linear pattern 70a at one place, and one second-surface-side linear pattern 60a intersects with one second linear pattern 72a at one place.

The second-surface-side linear patterns 60a are placed to be arranged in the Y-direction, and the first linear patterns 70a and the second linear patterns 72a are placed to be alternately arranged in the X-direction. Accordingly, the second-surface-side linear patterns 60a intersect with the first linear patterns 70a and the second linear patterns 72a in a lattice-shaped manner such that the second-surface-side linear patterns 60a face the first linear patterns 70a and the second linear patterns 72a at a plurality of places.

The second-surface-side linear pattern 60a includes a plurality of first facing portions 76 intersecting with the first linear patterns 70a in a facing manner, and a plurality of second facing portions 78 intersecting with the second linear patterns 72a in a facing manner.

In the V-shaped portion 62 constituting the second-surface-side linear pattern 60a, the first inclined portion 62a and the second inclined portion 62b are connected to each other at a distal end portion 62c. Further, the V-shaped portion 62 is connected to another V-shaped portion 62 adjacent to the V-shaped portion 62 via a connecting portion 62d.

The first facing portions 76 are each formed in the second-surface-side linear pattern 60a within a range which includes the connecting portion 62d and which does not reach its adjacent distal end portion 62c. Accordingly, as illustrated in FIG. 9A, the first facing portions 76 have a V-shape opened toward a second side in the Y-direction (toward the lower side on the plane of paper). The second facing portions 78 are each formed in the second-surface-side linear pattern 60a within a range which includes the distal end portion 62c and which does not reach its adjacent connecting portion 62d. Accordingly, as illustrated in FIG. 9A, the second facing portions 78 have a V-shape opened toward the first side in the Y-direction (toward the upper side on the plane of paper). Note that the shapes of the first facing portion 76 and the second facing portion 78 are linearly symmetric across a straight line parallel to the X-direction as a target axis and have the same length and the same linewidth.

FIG. 9B is a view illustrating the first facing portion 76 and the second facing portion 78. In FIG. 9B, the first facing portion 76 includes a first linear portion 76a constituted by the first inclined portion 62a, and a second linear portion 76b constituted by the second inclined portion 62b. A first end 76a1 of the first linear portion 76a and a first end 76b1 of the second linear portion 76b are connected to each other via the connecting portion 62d. On a bisector 77 that divides in half an angle formed between the first linear portion 76a and the second linear portion 76b, a direction from second ends 76a2, 76b2 of the linear portions 76a, 76b to the first ends 76a1, 76b1 is directed toward the first side in the Y-direction (the upper side on the plane of paper) as indicated by an arrow Y1 in the figure.

The second facing portion 78 includes a first linear portion 78a constituted by the first inclined portion 62a, and a second linear portion 78b constituted by the second inclined portion 62b. A first end 78a1 of the first linear portion 78a and a first end 78b1 of the second linear portion 78b are connected to each other via the distal end portion 62c. On a bisector 79 that divides in half an angle formed between the first linear portion 78a and the second linear portion 78b, a direction from second ends 78a2, 78b2 of the linear portions 78a, 78b to the first ends 78a1, 78b1 is directed toward the second side in the Y-direction (the lower side on the plane of paper) as indicated by an arrow Y2 in the figure.

Thus, respective directions of the first facing portion 76 and the second facing portion 78 on the bisectors 77, 79 are different from each other. That is, the first facing portions 76 and the second facing portions 78 are formed in respective V-shapes directed toward different sides in the Y-direction, and the directionality of the shape of the first facing portions 76 is different from the directionality of the shape of the second facing portions 78.

In the present embodiment, also by switching by the switch 6, deformations can be caused in respective parts of the deformable surface 2a, the respective parts corresponding to the first facing portions 76 and the second facing portions 78.

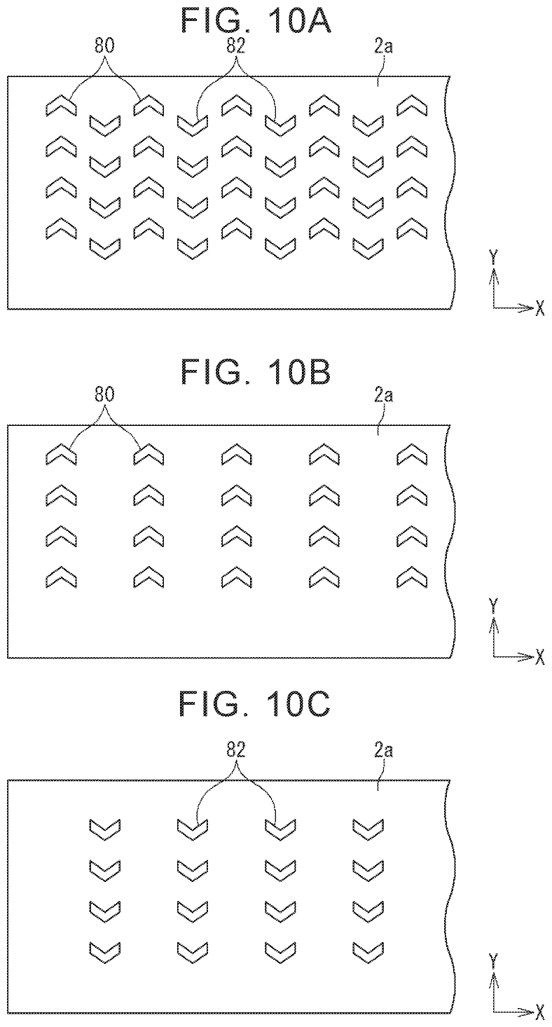

FIGS. 10A to 10C are views each illustrating a pattern of a deformation shape to appear on the deformable surface 2a in the second embodiment. FIG. 10A illustrates a deformation pattern when a voltage is applied between the second-surface-side electrode 24 and all the electrodes 70, 72 included in the first-surface-side electrode 22. In FIG. 10A, a plurality of first recesses 80 is recesses to appear in parts corresponding to the first facing portions 76. The first recesses 80 appear in a V-shape opened toward the second side in the Y-direction (toward the lower side on the plane of paper) so as to correspond to the contours of the first facing portions 76.

Further, a plurality of second recesses 82 is recesses to appear in parts corresponding to the second facing portions 78. The second recesses 82 appear in a V-shape opened toward the first side in the Y-direction (toward the upper side on the plane of paper) so as to correspond to the contours of the second facing portions 78. That is, the first recesses 80 and the second recesses 82 are opened in opposite directions, and thus, the directionality of the shape of the first recesses 80 is different from the directionality of the shape of the second recesses 82.

FIG. 10B illustrates a deformation pattern when a voltage is applied between the second-surface-side electrode 24 and the first electrode 70 of the first-surface-side electrode 22, and no voltage is applied to the second electrode 72. In this case, only the first recesses 80 appear on the deformable surface 2a so as to correspond to the first facing portions 76.

FIG. 10C illustrates a deformation pattern when a voltage is applied between the second-surface-side electrode 24 and the second electrode 72 of the first-surface-side electrode 22, and no voltage is applied to the first electrode 70. In this case, only the second recesses 82 appear on the deformable surface 2a so as to correspond to the second facing portions 78. Thus, in the present embodiment, the deformation patterns on the deformable surface 2a can be switched from one to another.

Further, in the present embodiment, since the directionality of the shape of the first linear patterns 70a is different from the directionality of the shape of the second linear patterns 72a, the directionality of the shape of the first recesses 80 can be made different from the directionality of the shape of the second recesses 82. Hereby, for example, like the relationship between the deformation pattern of FIG. 10B and the deformation pattern of FIG. 10C, the deformation patterns can have different directionalities, so that the directionalities of the deformation patterns on the deformable surface 2a can be switched.

Such a surface shape variable sheet 2 that can switch the directionalities on the deformable surface 2a can be used for a sliding surface under oil lubrication, for example, other than the conveying device. In this case, by switching the directionalities of the recesses in accordance with a sliding direction, the recesses on the deformable surface 2a can be functionalized as oil-sump grooves suitable for the sliding direction, thereby making it possible to achieve a reduction in frictional force on the sliding surface.

Further, the surface shape variable sheet 2 that can switch the directionalities on the deformable surface 2a can be also used for a passage switch provided in a liquid passage so as to switch passages for the liquid. In this case, by switching the directionalities on the deformable surface 2a, liquid passing on the deformable surface 2a is regulated, so that the passages for the liquid can be switched. Further, the surface shape variable sheet 2 that can switch the directionalities on the deformable surface 2a can be used for a switch for switching passages at the time when many micro-components and the like are conveyed, an alignment device for aligning many micro-components, and so on, as well as the passage switch for liquid.

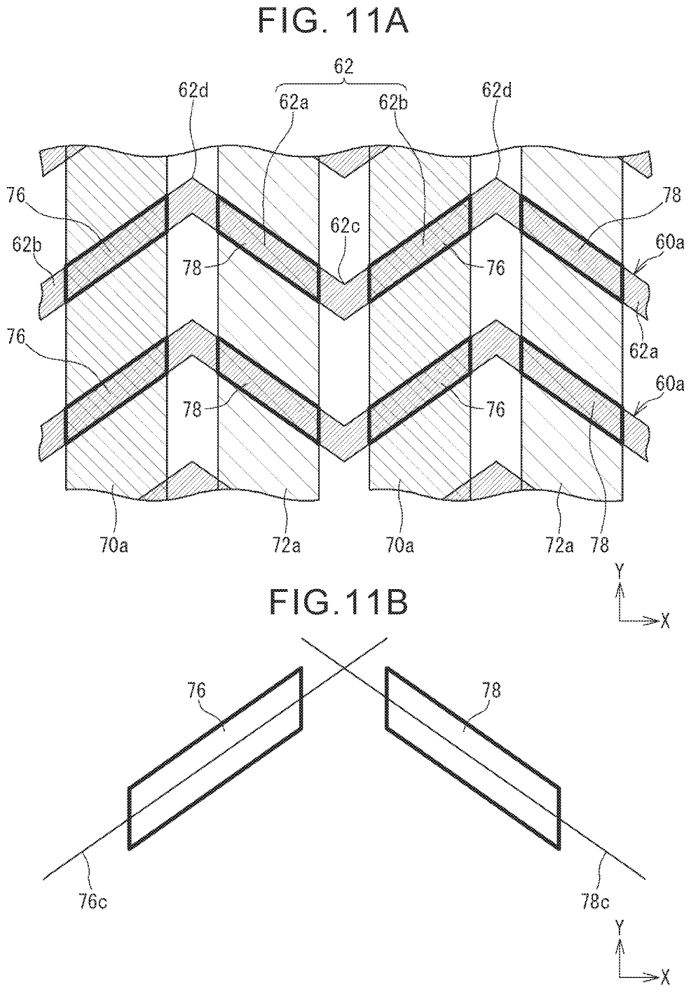

FIG. 11A is a view illustrating a positional relationship between the second-surface-side linear pattern 60a and each of the electrodes 70, 72 of the first-surface-side electrode 22 in a plan view of the deformable surface 2a of the surface shape variable sheet 2 according to a modification of the second embodiment.

In the present embodiment, the first linear pattern 70a intersects with the second inclined portion 62b of the V-shaped portion 62, and the first facing portion 76 is formed within a range of the second inclined portion 62b. Further, the second linear pattern 72a intersects with the first inclined portion 62a of the V-shaped portion 62, and the second facing portion 78 is formed within a range of the first inclined portion 62a.

As illustrated in FIG. 11A, the first facing portion 76 of the present embodiment has a linear shape inclined toward the first side in the Y-direction (the upper side on the plane of paper) as it goes toward the connecting portion 62d from the distal end portion 62c. Further, as illustrated in FIG. 11A, the second facing portion 78 has a linear shape inclined toward the second side in the Y-direction (the lower side on the plane of paper) as it goes toward the distal end portion 62c from the connecting portion 62d. Note that the shapes of the first facing portion 76 and the second facing portion 78 are linearly symmetric across a straight line parallel to the Y-direction as a target axis and have the same length and the same linewidth.

FIG. 11B is a view illustrating the first facing portion 76 and the second facing portion 78. As illustrated in FIG. 11B, the first facing portion 76 and the second facing portion 78 are provided such that extension lines 76c, 78c along respective linear directions of the first facing portion 76 and the second facing portion 78 intersect with each other. That is, the first facing portions 76 and the second facing portions 78 are formed in respective linear shapes inclined along different inclination directions, and in the present embodiment, the directionality of the shape of the first linear pattern 70a is different from the directionality of the shape of the second linear pattern 72a.

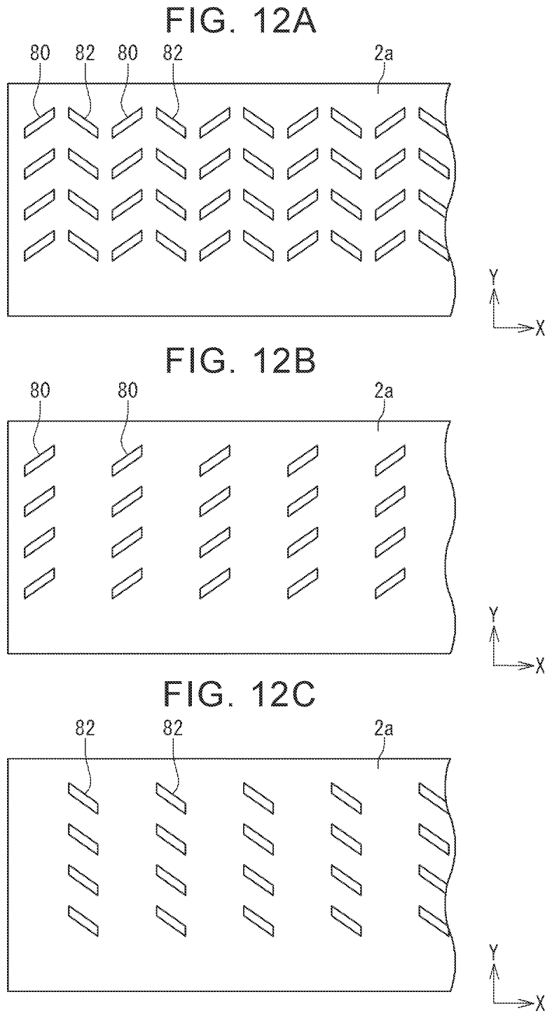

FIGS. 12A to 12C are views each illustrating a pattern of a deformation shape to appear on the deformable surface 2a in the modification. FIG. 12A illustrates a deformation pattern when a voltage is applied between the second-surface-side electrode 24 and all the electrodes 70, 72 included in the first-surface-side electrode 22. FIG. 12B illustrates a deformation pattern when a voltage is applied between the second-surface-side electrode 24 and the first electrode 70 of the first-surface-side electrode 22, and no voltage is applied to the second electrode 72. FIG. 12C illustrates a deformation pattern when a voltage is applied between the second-surface-side electrode 24 and the second electrode 72 of the first-surface-side electrode 22, and no voltage is applied to the first electrode 70.

Thus, in the present embodiment, the deformation patterns on the deformable surface 2a can be switched from one to another. Further, in the present embodiment, like the relationship between the deformation pattern of FIG. 12B and the deformation pattern of FIG. 12C, for example, the deformation patterns can have different directionalities, so that the directionalities of the deformation patterns on the deformable surface 2a can be switched.

Others

Note that the present disclosure is not limited to the above embodiments. The above embodiments deal with a case where the first-surface-side electrode 22 includes a plurality of electrodes electrically independent from each other. However, the first-surface-side electrode 22 may be constituted by a single electrode, and the second-surface-side electrode 24 may include a plurality of electrodes electrically independent from each other. Further, the first-surface-side electrode 22 and the second-surface-side electrode 24 may both include a plurality of electrodes electrically independent from each other. In this case, the number of combinations of electrodes to which a voltage is applied can be increased more. As a result, it is possible to increase the number of deformation patterns on the deformable surface 2a.

Further, the first embodiment deals with a case where the facing portions 46, 48, 50 have different lengths and different pitches (arrangement distances) in the X-direction. However, the facing portions 46, 48, 50 can be set to have different linewidths. Further, the facing portions 46, 48, 50 may be set to be different from each other in terms of at least one of length, linewidth, and pitch.

Further, the second embodiment and its modification deal with a case where the first facing portion 76 and the second facing portion 78 have the same length and the same linewidth. However, the first facing portion 76 and the second facing portion 78 may be set to be different from each other in terms of at least either one of length and linewidth. For example, when the linewidth of the first linear pattern 70a is set to be different from the linewidth of the second linear pattern 72a, it is possible to set the first facing portion 76 and the second facing portion 78 to have different lengths.

Further, the above embodiments deal with a case where the second dielectric sheet 26 is provided as another sheet body. However, the second-surface-side electrode 24 may be provided on the second surface 20b of the first dielectric sheet 20, and the second dielectric sheet 26 may be omitted.

What is claimed is:

1. A surface shape variable sheet comprising:
a sheet body made of an elastic material having dielectricity;
a first-surface-side electrode provided on a first surface side of the sheet body;
a second-surface-side electrode provided on a second surface side that is a back surface of the first surface, the second-surface-side electrode being configured such that a voltage is applied between the second-surface-side electrode and the first-surface-side electrode, wherein
the first-surface-side electrode includes a first electrode and a second electrode,
the first electrode faces a first part of the second-surface-side electrode via the sheet body, and
the second electrode faces a second part of the second-surface-side electrode via the sheet body, the second electrode being electrically independent from the first electrode on the first surface side.

2. The surface shape variable sheet according to claim 1, wherein:
the first electrode includes a first linear pattern;
the second electrode includes a second linear pattern extending along the same linear direction as the first linear pattern and arranged with the first linear pattern; and
the second-surface-side electrode includes a second-surface-side linear pattern including one or more first facing portions facing the first linear pattern and one or more second facing portions facing the second linear pattern.

3. The surface shape variable sheet according to claim 2, wherein the one or more first facing portions are different from the one or more second facing portions in terms of at least one of length and linewidth.

4. The surface shape variable sheet according to claim 2, wherein an arrangement distance between the first facing portions along the linear direction is different from an arrangement distance between the second facing portions along the linear direction.

5. The surface shape variable sheet according to claim 2, wherein:
the one first facing portion and the one second facing portion each include a first linear portion, and a second linear portion extending in a direction intersecting with a linear direction of the first linear portion;
a first end of the second linear portion is connected to a first end of the first linear portion; and
the one first facing portion is different from the one second facing portion in terms of a direction directed from second ends of the first linear portion and the second linear portion toward the first ends of the first linear portion and the second linear portion on a bisector that divides in half an angle formed between the first linear portion and the second linear portion.

6. The surface shape variable sheet according to claim 2, wherein:
the one first facing portion and the one second facing portion are formed in a linear shape and are placed to be distanced from each other; and
extension lines along respective linear directions of the one first facing portion and the one second facing portion intersect with each other.

7. The surface shape variable sheet according to claim 1, wherein:
the second-surface-side electrode includes a third electrode facing at least one of the first electrode and the second electrode via the sheet body, and a fourth electrode facing at least one of the first electrode and the second electrode via the sheet body.

8. The surface shape variable sheet according to claim 1, further comprising another sheet body made of an elastic material having dielectricity and laminated on either of the first surface and the second surface.

9. A surface shape variable device comprising:
a surface shape variable sheet including
a sheet body made of an elastic material having dielectricity,
a first-surface-side electrode provided on a first surface side of the sheet body, and
a second-surface-side electrode provided on a second surface side that is a back surface of the first surface, the second-surface-side electrode being configured such that a voltage is applied between the second-surface-side electrode and the first-surface-side electrode,
the first-surface-side electrode including
a first electrode facing a first part of the second-surface-side electrode via the sheet body, and
a second electrode facing a second part of the second-surface-side electrode via the sheet body, the second electrode being electrically independent from the first electrode on the first surface side;
a power supply configured to apply a voltage between the first-surface-side electrode and the second-surface-side electrode;
a first switch provided between the power supply and the first electrode; and
a second switch provided between the power supply and the second electrode.
